(19) United States
(12) Patent Application Publication
(10) Pub. No.: US 2004/0036383 A1
(43) Pub. Date: Feb. 26, 2004

(54) Elliptical electrode for crystals

(76) Inventor: Robert Walter Rubach, Burlington, WI (US)

Correspondence Address: Mark P. Bourgeois, CTS Corporation, 905 West Boulevard North, Elkhart, IN, 46514, US

(21) Appl. No.: 10/226,724

(22) Filed: Aug. 23, 2002

(51) Int. Cl. H01L 41/047

(52) U.S. Cl. 310/365

(57) ABSTRACT

A crystal electrode that has improved pullability from the nominal resonating frequency. A crystal has a top surface and a bottom surface. An elliptical shaped electrode is located on the top surface. Another elliptical shaped electrode is located on the bottom surface.

### BACKGROUND OF THE INVENTION

1. Field of the Invention

This invention relates to oscillators that provide a stable reference source or frequency in computers or other electronic equipment. Specifically, there is an electrode configuration for a crystal resonating device that provides less mode coupling and improved spurious noise suppression, while maximizing the pullability of the resonator.

2. Description of the Prior Art

Various devices are well known for providing a reference frequency or source. Such devices are called oscillators. The oscillator typically has a quartz crystal source and also has electronic compensation circuitry to stabilize the output frequency. Ovenized oscillators heat the oscillator to a uniform temperature to obtain a more stable output frequency. The oscillators have been packaged on various support structures and in housings such as metal cans.

The quartz crystals have electrodes patterned on each side of the crystal. The electrodes are used to apply a voltage across the crystal. The electrodes are typically made by vacuum thin film depositing a metal such as gold through a mask onto the surface of the crystal. The electrodes would be attached to another electrical contact such as a substrate pad or a crystal clip in order to make an electrical connection to another electrical circuit such as an oscillator whose frequency is desired to be stabilized. As the crystal frequency is increased, the required area of the electrodes decreases.

Referring to FIG. 1, an equivalent circuit of a quartz crystal is shown. The quartz crystal may be represented by an L,C,R circuit. CO is the static capacitance formed by the crystal electrodes plus any holder capacitance. The L1, C1, R1 branch is called the “motional arm”. The motional capacitance, C1, controls the “pullability” of the crystal. It is desired for the crystal to remain in a phase locked loop state when differing capacitances are applied to pull it off of the nominal oscillating frequency. The motional capacitance is the capacitance of the motional (series) arm of the equivalent circuit. The shift of the frequency of a crystal (Fshift) can be calculated by the following formula:

Fshift=C1/2(C0+CL)

CL is the load capacitance and is the effective external capacitance associated with the crystal that determines the load resonance frequency FL. If two different loads on the crystal are known, we can look at the differences between each shift from series to calculate the total trim range. C1 and R1 can be specified on any crystal. Typical values of R1 are 10 to 25 ohms on the fundamental mode and higher on overtones. Typical motional capacitance values are between 0.018 pf and 0.024 pf for a fundamental crystal. Motional capacitance is divided by the overtone squared. Static capacitance (CO) is about 213 times C1 in the fundamental mode.

The pullability of a crystal resonator in a voltage controlled crystal oscillator (VCXO) depends on C1, CO and CL. It is desired to minimize CO with respect to C1 to obtain maximum pull.

One way to minimize CO with respect to C1 is to use circular electrodes on a circular blank.

On a rectangular crystal blank, the rectangular electrode shape is far from ideal.

A current unmet need exists for an electrode design for a rectangular crystal that minimizes static capacitance with respect to motional capacitance in order to obtain maximum pullability.

### SUMMARY OF THE INVENTION

It is a feature of the invention to provide a crystal electrode that has improved pullability from the nominal resonating frequency.

Yet, another feature of the invention is to provide an electrode for a crystal that includes a crystal having a top surface and a bottom surface. A first elliptical shaped electrode is located on the top surface. A second elliptical shaped electrode is located on the bottom surface.

### BRIEF DESCRIPTION OF THE DRAWINGS

FIG. 1 is an equivalent circuit of a quartz crystal.

FIG. 2 is a top view of the preferred embodiment of the present invention.

FIG. 3 is a bottom view of FIG. 1.

FIG. 4 is a cross-sectional view of FIG. 1.

FIG. 5 is a top view of another embodiment of the present invention.

FIG. 6 is a bottom view of FIG. 5.

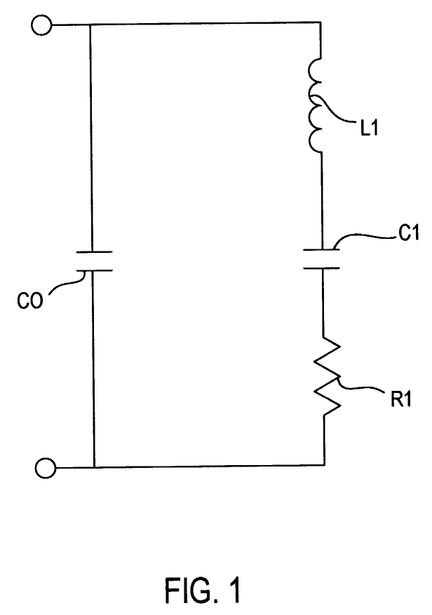

It is noted that the drawings of the invention are not to scale. In the drawings, like numbering represents like elements between the drawings.

### DETAILED DESCRIPTION OF THE PREFERRED EMBODIMENT(S)

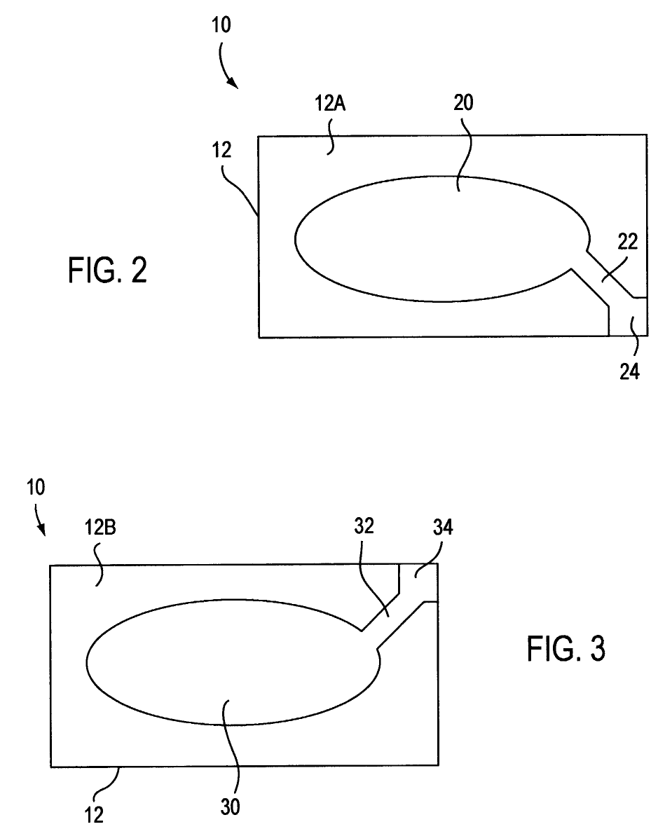

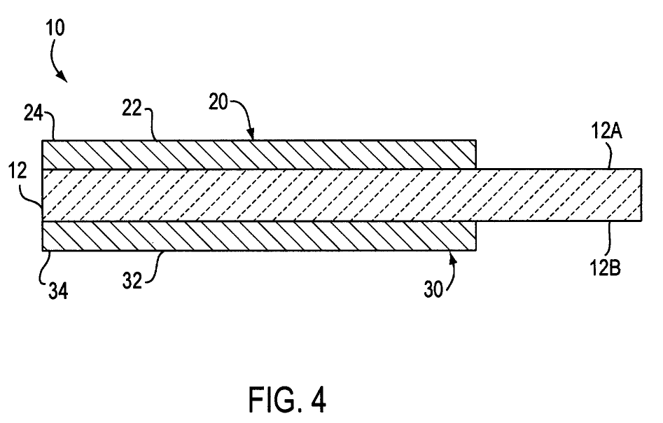

Referring to FIGS. 2-4, a crystal 10 is shown. A conventional quartz crystal blank 12 has a top surface 12A and a bottom surface 12B. An elliptical shaped top electrode 20 is located on top surface 12A and an elliptical shaped bottom electrode 30 is located on bottom surface 12B. Top electrode 20 has a contact pad 24 and a connection portion 22. Similarly, bottom electrode 30 has a contact pad 34 and a connection portion 32. The contact pads would be attached to another electrical contact such as a substrate pad or a crystal clip in order to make an electrical connection to another electrical circuit such as an oscillator whose frequency is desired to be stabilized. Electrodes 20 and 30 are located opposite each other on opposite sides of crystal 12. It is noted that the electrodes have an elliptical shape.

The vibrational area in an elongated AT resonator is elliptical in nature. The vibrational amplitude is strongest at the center of the crystal and drops off in both the x and z directions toward the edges. An electrode that follows this vibrational amplitude is elliptical shaped for an rectangular AT quartz crystal.

By designing an electrode to closely match the actual vibrational area, the contribution to the static capacitance Co of the resonator by stray fringing effects past the vibrational edge are minimized. Because quartz is an anisotropic material, the vibrational amplitude decreases differently in different directions. In order to maximize capacitance C1, a crystal length 15% longer than the width is needed. This is for the difference in amplitude decay only. Therefore, the electrodes have a longer length dimension than width dimension.

Alternative Embodiment

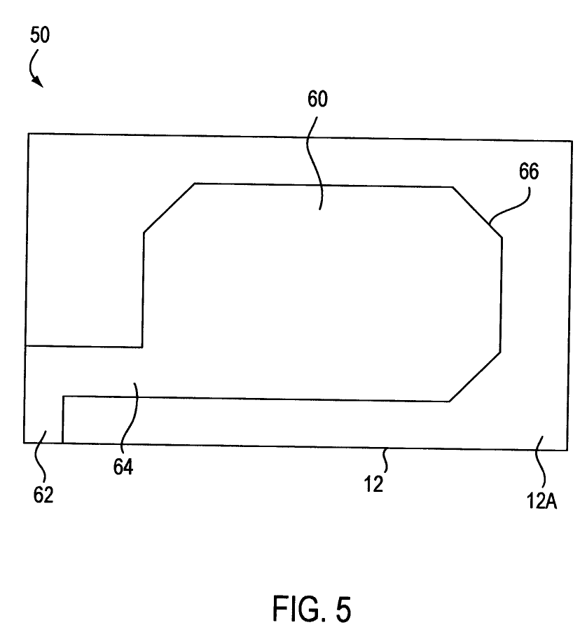

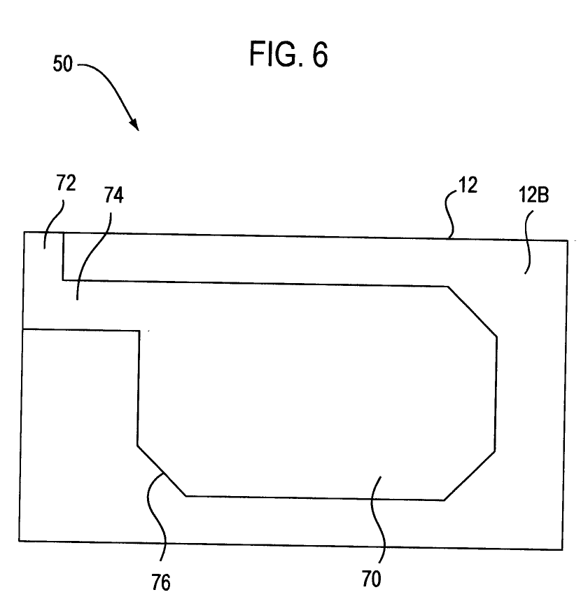

Referring to FIGS. 5 and 6, a crystal 50 is shown. A conventional quartz crystal blank 12 has a top surface 12A and a bottom surface 12B. A rectangular shaped top electrode 60 is located on top surface 12A and a rectangular shaped bottom electrode 70 is located on bottom surface 12B. Top electrode 60 has a contact pad 62, a connection portion 64 and an angled corner 66. Similarly, bottom electrode 70 has a contact pad 72, a connection portion 74 and an angled corner 76. The contact pads would be attached to another electrical contact such as a substrate pad or a crystal clip in order to make an electrical connection to another electrical circuit such as an oscillator whose frequency is desired to be stabilized. Electrodes 60 and 70 are located opposite each other on opposite sides of crystal 12. It is noted that the electrodes have angled corners and the areas that are removed are triangular shaped. The size of the angled corners is determined by the operating frequency and the length and width of the crystal.

While the invention has been taught with specific reference to these embodiments, someone skilled in the art will recognize that changes can be made in form and detail without departing from the spirit and the scope of the invention. The described embodiments are to be considered in all respects only as illustrative and not restrictive. The scope of the invention is, therefore, indicated by the appended claims rather than by the description. All changes that come within the meaning and range of equivalency of the claims are to be embraced within their scope.

What is claimed is:

1. An electrode for a crystal, comprising:
a) a crystal having a top surface and a bottom surface;
b) a first elliptical shaped electrode disposed on the top surface; and
c) a second elliptical shaped electrode disposed on the bottom surface.

2. The electrode according to claim 1, wherein the electrode has a contact pad and a connection portion.

3. The electrode according to claim 1, wherein the elliptical electrode is located in the center of the crystal.

4. The electrode according to claim 2, wherein the contact pad is located adjacent an outer edge of the crystal.

5. The electrode according to claim 1, wherein the crystal is mounted in an oscillator.

6. The electrode according to claim 1, wherein the first and second electrodes are arranged such that the electrodes overlap.

7. The electrode according to claim 1, wherein the crystal is a rectangular AT crystal.

8. A crystal for an oscillator, comprising:
a) a crystal blank having a top surface and a bottom surface;
b) a first electrode mounted on the top surface, the first electrode having a length and a width dimension, the length dimension having a magnitude that is greater than the width dimension; and
c) a second electrode mounted on the bottom surface, the second electrode having a length and a width dimension, the length dimension having a magnitude that is greater than the width dimension.

9. The crystal according to claim 8, wherein the electrode is elliptical shaped.

10. The crystal according to claim 8, wherein the electrodes have a contact pad and a connection portion.

11. The crystal according to claim 8, wherein the electrodes are located in the center of the crystal.

12. The crystal according to claim 10, wherein the contact pad is located adjacent an outer edge of the crystal.

13. The crystal according to claim 8, wherein the crystal is mounted in an oscillator.

14. The crystal according to claim 8, wherein the first and second electrodes are arranged such that the electrodes overlap.

15. The crystal according to claim 8, wherein the crystal blank is a rectangular AT crystal blank.

16. The crystal according to claim 12, wherein the contact pad is connected to an external electrical circuit.

17. The crystal according to claim 8, wherein the electrode has rounded corners.

18. The crystal according to claim 8, wherein the electrode has angled corners.
